(19) United States
(12) Patent Application Publication
(10) Pub. No.: US 2026/0005669 A1
(43) Pub. Date: Jan. 1, 2026

(54) BULK ACOUSTIC WAVE DEVICE WITH RECESSED FRAME STRUCTURE IN ACOUSTICALLY ACTIVE REGION

(71) Applicant: Skyworks Global Pte. Ltd., Singapore (SG)

(72) Inventors: Yanbo He, Irvine, CA (US); Kwang Jae Shin, Yongin-si (KR); Zongliang Cao, Irvine, CA (US)

(21) Appl. No.: 19/244,282

(22) Filed: Jun. 20, 2025

Related U.S. Application Data
(60) Provisional application No. 63/665,970, filed on Jun. 28, 2024.
(60) Provisional application No. 63/665,974, filed on Jun. 28, 2024.
(60) Provisional application No. 63/666,015, filed on Jun. 28, 2024.

(51) Int. Cl. H03H 9/17; H03H 9/05; H03H 9/56

(52) U.S. Cl. CPC H03H 9/172; H03H 9/0504; H03H 9/568

(57) ABSTRACT

Aspects of this disclosure relate to a bulk acoustic wave resonator having an acoustically active region and a peripheral region. The bulk acoustic wave resonator can include a first electrode, a second electrode, a piezoelectric layer positioned between the first electrode and the second electrode, and a recessed frame structure at least partially in the acoustically active region. The piezoelectric layer can have an effective piezoelectric coefficient with a lower magnitude in the peripheral region than in the acoustically active region. Other embodiments of bulk acoustic wave resonators are disclosed. Related filters, multiplexers, radio frequency modules, radio frequency systems, wireless communication devices, and methods are disclosed.

### CROSS REFERENCE TO PRIORITY APPLICATIONS

Any and all applications for which a foreign or domestic priority claim is identified in the Application Data Sheet as filed with the present application are hereby incorporated by reference under 37 C.F.R. § 1.57. This application claims the benefit of priority of U.S. Provisional Application No. 63/665,970, filed Jun. 28, 2024 and titled “BULK ACOUSTIC WAVE DEVICE WITH RECESSED FRAME STRUCTURE IN ACOUSTICALLY ACTIVE REGION,” and claims the benefit of priority of U.S. Provisional Application No. 63/665,974, filed Jun. 28, 2024 and titled “BULK ACOUSTIC WAVE DEVICE WITH RECESSED FRAME STRUCTURE IN PERIPHERAL REGION,” and claims the benefit of priority of U.S. Provisional Application No. 63/666,015, filed Jun. 28, 2024 and titled “FRAME STRUCTURE IN BULK ACOUSTIC WAVE DEVICE,” the disclosures of each of which are hereby incorporated by reference in their entireties and for all purposes.

### BACKGROUND

### Technical Field

The disclosed technology relates to acoustic wave devices. Embodiments of this disclosure relate to bulk acoustic wave resonators with recessed frame structures.

### Description of Related Technology

Acoustic wave filters can be implemented in radio frequency electronic systems. For instance, filters in a radio frequency front end of a mobile phone can include acoustic wave filters. An acoustic wave filter can be a band pass filter. A plurality of acoustic wave filters can be arranged as a multiplexer. For example, two acoustic wave filters can be arranged as a duplexer.

An acoustic wave filter can include a plurality of acoustic wave resonators arranged to filter a radio frequency signal. Example acoustic wave resonators include surface acoustic wave (SAW) resonators and bulk acoustic wave (BAW) resonators. In BAW resonators, acoustic waves propagate in the bulk of a piezoelectric layer. Example BAW resonators include film bulk acoustic wave resonators (FBARs) and BAW solidly mounted resonators (SMRs).

For BAW devices, achieving a high quality factor (Q) is generally desirable. Suppressing and/or attenuating spurious mode(s) in BAW devices is also generally desirable. There are technical challenges related to increasing Q and further suppressing spurious mode(s) while meeting other performance specifications for BAW devices.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a bulk acoustic wave resonator having an acoustically active region and a peripheral region. The bulk acoustic wave resonator includes electrodes including a first electrode and a second electrode, a piezoelectric layer positioned between the first electrode and the second electrode, and a recessed frame structure at least partially in the acoustically active region. The piezoelectric layer has an effective piezoelectric coefficient with a lower magnitude in the peripheral region than in the acoustically active region.

The bulk acoustic wave resonator can include a passivation layer including a first portion and a second portion thinner than the first portion, where the recessed frame structure includes the second portion of the passivation layer. The second electrode can be positioned between the piezoelectric layer and the passivation layer. The bulk acoustic wave resonator can include an oxide raised frame structure in the peripheral region.

The recessed frame structure can be offset from the peripheral region.

A majority of the recessed frame structure can be in the acoustically active region. An entirety of the recessed frame structure can be in the acoustically active region.

The bulk acoustic wave resonator can include a raised frame structure in the peripheral region. The raised frame structure can include a metal layer in contact with the second electrode. The raised frame structure can include a dielectric layer between the piezoelectric layer and the second electrode.

The first electrode can have a first thickness in the acoustically active region and a second thickness in the peripheral region, where the second thickness is greater than the first thickness. A magnitude of a positive mass loading provided by a thickness difference between the first and second thicknesses can be greater than a magnitude of a negative mass loading provided by the recessed frame structure.

The bulk acoustic wave resonator can include a seed layer in the peripheral region between the first electrode and the piezoelectric layer.

The recessed frame structure can include a recessed portion of the second electrode.

Another aspect of this disclosure is a bulk acoustic wave resonator having an acoustically active region and a peripheral region. The bulk acoustic wave resonator includes a first electrode, a second electrode, a piezoelectric layer positioned between the first electrode and the second electrode, and a recessed frame structure at least partially in the acoustically active region. The first electrode includes a thinner portion in the acoustically active region and a thicker portion in the peripheral region. The thicker portion is thicker than the thinner portion. The piezoelectric layer has an effective piezoelectric coefficient with a lower magnitude in the peripheral region than in the acoustically active region.

A magnitude of a positive mass loading provided by the thicker portion can be greater than a magnitude of a negative mass loading provided by the recessed frame structure.

The recessed frame structure can be completely in the acoustically active region. The recessed frame structure can be offset from the peripheral region.

The recessed frame structure can include a recessed portion of the second electrode.

The bulk acoustic wave resonator can include a seed layer positioned between the first electrode and the piezoelectric layer in the peripheral region.

The bulk acoustic wave resonator can include an air cavity. The first electrode can be positioned between the air cavity and the piezoelectric layer.

The bulk acoustic wave resonator can include a raised frame structure in the peripheral region.

Another aspect of this disclosure is a bulk acoustic wave resonator having an acoustically active region and a peripheral region. The bulk acoustic wave resonator includes electrodes including a first electrode and a second electrode, a piezoelectric layer positioned between the first electrode and the second electrode, and a recessed frame structure in the peripheral region. The piezoelectric layer has an effective piezoelectric coefficient with a lower magnitude in the peripheral region than in the acoustically active region.

The second electrode can include a first portion and a second portion thinner than the first portion, where the recessed frame structure includes the second portion of the second electrode. The first electrode can include a thinner portion in the acoustically active region and a thicker portion in the peripheral region. A thickness difference between the first and second portions of the second electrode can be greater than a thickness difference of the thinner and thicker portions of the first electrode.

The bulk acoustic wave resonator can include a seed layer in the peripheral region between the first electrode and the piezoelectric layer.

The recessed frame structure can be offset from the acoustically active region.

The bulk acoustic wave resonator can include a raised frame structure. The recessed frame structure can be positioned between the acoustically active region and the raised frame structure. The raised frame structure can include a dielectric layer. The dielectric layer can be positioned between the piezoelectric layer and the second electrode.

Another aspect of this disclosure is a bulk acoustic wave resonator having an acoustically active region and a peripheral region. The bulk acoustic wave resonator includes a first electrode, a second electrode, a piezoelectric layer positioned between the first electrode and the second electrode, and a recessed frame structure. The first electrode includes a first portion in the acoustically active region and a second portion in the peripheral region. The second portion is thicker than the first portion. The piezoelectric layer has an effective piezoelectric coefficient with a lower magnitude in the peripheral region than in the acoustically active region.

The recessed frame structure can be at least partially in the acoustically active region. The recessed frame structure can be fully in the acoustically active region and offset from the peripheral region. The recessed frame structure can include a third portion of the first electrode that is thinner than the first portion.

The bulk acoustic wave resonator can include a raised frame structure in the peripheral region. The raised frame structure can include the second portion of the first electrode. The raised frame structure can include a dielectric layer.

The bulk acoustic wave resonator can include a passivation layer, where the second electrode is positioned between the piezoelectric layer and the passivation layer. The passivation layer can include a recessed portion, and the recessed frame structure can include the recessed portion of the passivation layer.

The recessed frame structure can be positioned in the peripheral region.

The first portion of the first electrode can span the acoustically active region. The second portion of the first electrode can span the peripheral region.

The bulk acoustic wave resonator can include a seed layer positioned between the first electrode and the piezoelectric layer in the peripheral region.

The bulk acoustic wave resonator can include an air cavity. The first electrode can be positioned between the air cavity and the piezoelectric layer.

A difference in thicknesses between the first and second portions of the first electrode can be due to over etching the first electrode in the acoustically active region.

Another aspect of this disclosure is a method of manufacturing a bulk acoustic wave resonator having an acoustically active region and a peripheral region. The method includes over etching an electrode of the bulk acoustic wave resonator in the acoustically active region such that the electrode is thinner in the acoustically active region than in the peripheral region; forming a piezoelectric layer over the electrode such that the piezoelectric layer has an effective piezoelectric coefficient with a lower magnitude in the peripheral region than in the acoustically active region; and forming a recessed frame structure of the bulk acoustic wave resonator.

Forming the recessed frame structure can be performed after the forming the piezoelectric layer.

Forming the recessed frame structure can be performed before the forming the piezoelectric layer.

The recessed frame structure can be in the acoustically active region.

The recessed frame structure can be in the peripheral region.

Another aspect of this disclosure is an acoustic wave filter for filtering a radio frequency signal. The acoustic wave filter includes a bulk acoustic wave resonator in accordance with any suitable principles and advantages disclosed herein and a plurality of additional acoustic wave resonators. The bulk acoustic wave resonator and the plurality of additional acoustic wave resonators are configured to filter the radio frequency signal.

Another aspect of this disclosure is a multiplexer for filtering radio frequency signals. The multiplexer includes a first filter including a bulk acoustic wave resonator in accordance with any suitable principles and advantages disclosed herein, and a second filter coupled to the first filter at a common node.

Another aspect of this disclosure is a radio frequency module that includes a filter including a bulk acoustic wave resonator in accordance with any suitable principles and advantages disclosed herein, radio frequency circuitry, and a package structure enclosing the filter and the radio frequency circuitry.

Another aspect of this disclosure is a radio frequency system that includes an antenna, a filter including a bulk acoustic wave resonator in accordance with any suitable principles and advantages disclosed herein, and an antenna switch configured to selectively electrically connect the antenna and a signal path that includes the filter.

Another aspect of this disclosure is a wireless communication device that includes a radio frequency front end including a filter that includes a bulk acoustic wave resonator in accordance with any suitable principles and advantages disclosed herein, an antenna coupled to the radio frequency front end, a transceiver in communication with the radio frequency front end, and a baseband system in communication with the transceiver.

Another aspect of this disclosure is a method of radio frequency signal processing. The method includes receiving a radio frequency signal via at least an antenna; and filtering the radio frequency signal with a filter that includes a bulk acoustic wave resonator in accordance with any suitable principles and advantages disclosed herein.

For purposes of summarizing the disclosure, certain aspects, advantages and novel features of the innovations have been described herein. It is to be understood that not necessarily all such advantages may be achieved in accordance with any particular embodiment. Thus, the innovations may be embodied or carried out in a manner that achieves or optimizes one advantage or group of advantages as taught herein without necessarily achieving other advantages as may be taught or suggested herein.

### BRIEF DESCRIPTION OF THE DRAWINGS

Embodiments of this disclosure will now be described, by way of non-limiting example, with reference to the accompanying drawings.

FIG. 1A is a schematic cross-sectional side view of a bulk acoustic wave (BAW) device according to an embodiment.

FIG. 1B is a schematic cross-sectional side view of a portion of the BAW device of FIG. 1A.

FIGS. 1C-1, 1C-2, 1C-3, and 1C-4 are graphs showing simulated quality factor contours of the BAW device of FIG. 1A.

FIG. 2 is a schematic cross-sectional side view of a portion of a BAW device according to an embodiment.

FIG. 3 is a graph showing simulated frequency responses of two different BAW devices.

FIG. 4 is a schematic cross-sectional side view of a portion of a BAW device according to an embodiment.

FIG. 5A is a simulated spur intensity contour map of the BAW device of FIG. 4. FIG. 5B is a simulated quality factor contour map of the BAW device of FIG. 4.

FIG. 5C is another simulated spur intensity contour map of the BAW device of FIG. 4.

FIG. 5D is a graph showing simulated frequency responses of two different BAW devices.

FIG. 6 is a schematic cross-sectional side view of a portion of a BAW device according to an embodiment.

FIG. 7 is a schematic cross-sectional side view of a portion of a BAW device according to an embodiment.

FIG. 8 is a schematic cross-sectional side view of a portion of a BAW device according to an embodiment.

FIG. 9A is an example schematic top plan view of a BAW device according to an embodiment. FIG. 9B is another example plan view of a BAW device according to an embodiment.

FIG. 10 is an example of a BAW solidly mounted resonator (SMR) according to an embodiment.

FIG. 11 is an example of a BAW SMR according to an embodiment.

FIG. 12A is a schematic diagram of a ladder filter that includes one or more BAW resonators according to an embodiment.

FIG. 12B is schematic diagram of a band pass filter.

FIGS. 13A, 13B1, 13C, and 13D are schematic diagrams of multiplexers that include a filter with one or more BAW resonators according to an embodiment.

FIGS. 14, 15, and 16 are schematic block diagrams of modules that include a filter with one or more BAW resonators according to an embodiment.

FIG. 17 is a schematic block diagram of a wireless communication device that includes a filter with one or more BAW resonators according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Any suitable principles and advantages of the embodiments disclosed herein can be implemented together with each other.

Acoustic wave filters can filter radio frequency (RF) signals in a variety of applications, such as in an RF front end of a mobile phone. An acoustic wave filter can be implemented with bulk acoustic wave (BAW) devices. A film acoustic wave resonator (FBAR) and a BAW solidly mounted resonator (SMR) are examples of BAW devices. Increasing the quality factor (Q) of a given bulk acoustic wave (BAW) resonator can effectively reduce energy losses. Such energy losses can include, for example, insertion losses within a filter or phase noise in an oscillator. BAW resonator performance can be enhanced and/or optimized by one or more of area, geometry, frame structure, or the like. BAW devices disclosed herein can achieve improved performance by engineering a peripheral region of a piezoelectric layer and including a frame structure.

BAW devices can include frame structures. A frame structure is a structure that adjusts mass loading in a portion of a BAW device over an acoustic reflector. A frame structure can include a raised frame structure that adds mass loading and/or a recessed frame structure that reduces mass loading. A raised frame structure can include an additional layer and/or a thicker portion of layer that increases mass loading in a portion of a BAW device relative to a main acoustically active region. In some applications, a raised frame layer can include a different material than layers in contact with the raised frame layer. In some applications, a raised frame layer can include a same material as a layer in contact with the raised frame layer. A raised frame structure can be a multi-layer structure that includes two or more raised frame layers. A recessed frame structure can include a thinner portion of a layer of a BAW device that decreases mass loading in a portion of the BAW device relative to a main acoustically active region. Certain BAW devices include a frame structure around the main acoustically active region of the BAW device. Such a frame structure can be included around a periphery of the BAW device. In certain applications, the frame structure can surround the main acoustically active region in plan view. In some other applications, the frame structure can be around some but not all of the main acoustically active region in plan view.

A BAW device can include a first electrode, a second electrode, and a piezoelectric layer positioned between the first and second electrodes. A frame structure, such as a raised frame and/or a recessed frame, can be positioned around a main acoustically active region of the BAW device to reduce lateral energy leakage from the main acoustically active region. A region of the BAW device that includes the frame structure can be referred to as a frame region. In certain applications, a raised frame structure can create a resonance at a frequency that is below a resonant frequency of the main acoustically active region of the BAW device when the raised frame structure overlaps with the pair of electrodes and the piezoelectric layer over the acoustic reflector. This resonance can be below a main resonant frequency of the BAW device. A resonance associated with the raised frame structure can be referred to as a frame mode, and more specifically a raised frame mode. The raised frame mode can be undesirable in certain applications.

At least a portion of the piezoelectric layer in the frame region can be engineered to suppress one or more frame modes. A method of forming an engineered region in the piezoelectric layer can involve providing a seed layer and etching the seed layer from the acoustically active region. During this process, a lower electrode of the BAW device can be over etched. With such over etching, a recessed frame region with a recessed frame structure positioned vertically relative to the engineered region of the piezoelectric layer may not have less mass loading that in the acoustically active region. This can degrade recessed frame performance. In certain instances, the BAW device can have a relatively strong lateral mode below resonant frequency fs. It can be challenging to design a recessed frame structure that can suppress the lateral mode. It can be more challenging to design a recessed frame structure that can suppress the lateral mode when the piezoelectric layer includes an engineered region and/or when an electrode is over etched in the acoustically active region.

Embodiments of this disclosure relate to BAW devices (e.g., BAW resonators) that include an engineered region of a piezoelectric layer and a recessed frame structure. The engineered region of the piezoelectric layer can be positioned vertically relative to a raised frame structure to suppress a raised frame mode. This disclosure provides recessed frame designs for such BAW devices where an electrode of the BAW device is thinner in the acoustically active region than in the engineered region, for example, due to over etching associated with engineering the engineered region of the piezoelectric layer. BAW devices with such recessed frames can also provide desirable lateral mode suppression.

A BAW device according to some embodiments can include an acoustic reflector, a first electrode, a second electrode, and a piezoelectric layer positioned between the first electrode and the second electrode. A region where the first electrode, the second electrode, and the piezoelectric layer overlap over the acoustic reflector and generate an acoustic wave can define an acoustically active region of the BAW device. The acoustically active region can include a main acoustically active region corresponding to a main resonant frequency of the BAW device. The BAW device can include a frame region outside of the main acoustically active region, where the frame region includes a frame structure. The BAW device can include a peripheral region outside of the acoustically active region. The piezoelectric layer in the peripheral region can be engineered. The engineered region of the piezoelectric layer has a lower magnitude effective piezoelectric coefficient than the piezoelectric layer in the acoustically active region. The frame region and the peripheral region can at least partially overlap one another.

The BAW device can include a frame structure in the frame region. The frame structure can include a recessed frame structure and/or a raised frame structure. The recessed frame structure can be positioned in the acoustically active region or be positioned in the peripheral region that is outside of the acoustically active region. The raised frame structure can be positioned in the peripheral region and outside of the acoustically active region. In some embodiments, a recessed frame portion of the frame region can overlap the acoustically active region. In such embodiments, a region of the acoustically active region that does not overlap the frame region can be the main acoustically active region. BAW devices with an engineered region of a piezoelectric layer and a recessed frame structure disclosed herein can achieve frame mode suppression and lateral mode suppression.

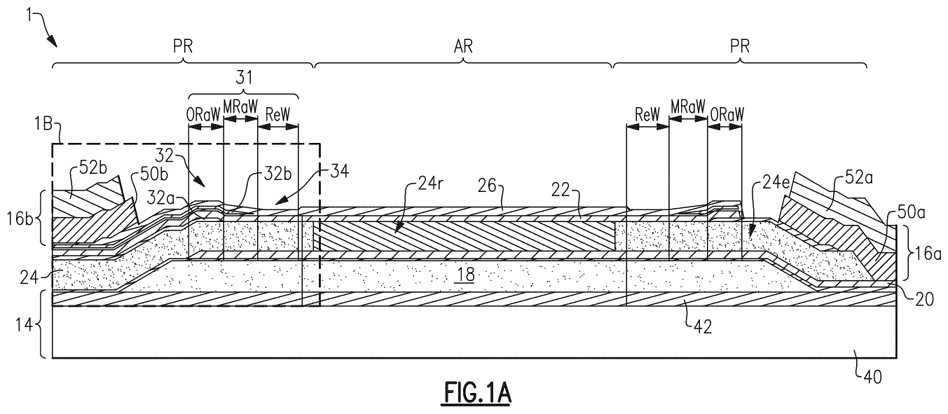

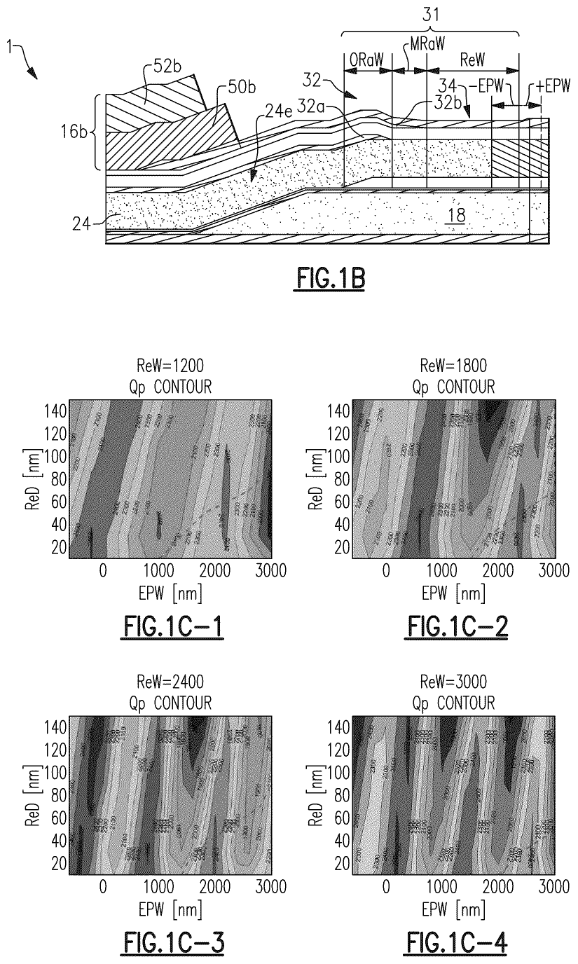

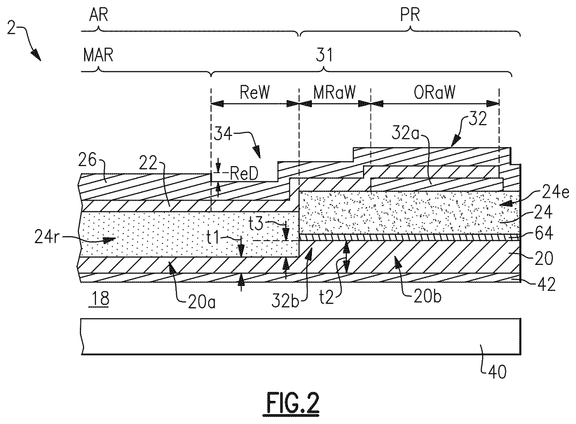

FIG. 1A is a schematic cross-sectional side view of a BAW device 1 according to an embodiment. FIG. 1B is a schematic cross-sectional side view of a portion 1B of the BAW device 1 of FIG. 1A. The BAW device 1 can include an acoustic reflector (e.g., a cavity 18), a first electrode 20, a second electrode 22, and a piezoelectric layer 24. The piezoelectric layer 24 includes an engineered region 24e. A region of the piezoelectric layer 24 that is not engineered can be referred to as a regular region 24r of the piezoelectric layer 24. A passivation layer 26 can be provided over the second electrode 22.

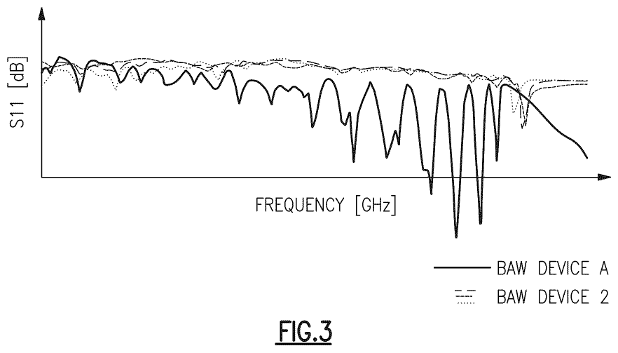

A region where the first electrode 20, the second electrode 22, and the piezoelectric layer 24 overlap over the acoustic reflector (e.g., the cavity 18) and generate an acoustic wave can define an acoustically active region AR of the BAW device 1. The first electrode 20, the second electrode 22, and the regular region 24r of the piezoelectric layer 24 overlap in the acoustically active region AR of the BAW device 1. The acoustically active region AR can include or be a main acoustically active region corresponding to a main resonant frequency of the BAW device 1. The BAW device 1 can include a peripheral region PR outside of the acoustically active region AR. The piezoelectric layer 24 in the peripheral region PR is engineered and the engineered region 24e of the piezoelectric layer 24 has a lower magnitude effective piezoelectric coefficient than the regular region 24r of the piezoelectric layer 24 in the acoustically active region AR. The BAW device 1 can include a frame region that includes a frame structure 31. The frame region and the peripheral region PR can at least partially overlap. In some embodiments, a recessed frame portion of the frame region can at least partially overlap the acoustically active region AR (see, for example, FIGS. 2, 4, 7, 8, and 10). In such embodiments, a region of the acoustically active region AR that does not overlap the frame region can be the main acoustically active region.

As illustrated, the BAW device 1 includes a frame structure 31 in the frame region. The frame structure 31 can include a raised frame structure 32 and/or a recessed frame structure 34. The recessed frame structure 34 can be positioned in the peripheral region PR that is outside of the acoustically active region AR, for example, as illustrated in FIG. 1A. In certain embodiments, the recessed frame structure 34 can be positioned in the acoustically active region AR, for example, as shown in FIGS. 2, 4, 7, 8, and 10.

The engineered region 24e of the piezoelectric layer 24 can have a lower magnitude effective piezoelectric coefficient than the regular region 24r of the piezoelectric layer 24 in the acoustically active region AR. For example, the engineered region 24e of the piezoelectric layer 24 can have an effective piezoelectric coefficient magnitude that is less than 50% of the effective piezoelectric coefficient magnitude of the regular region 24r of the piezoelectric layer 24 in the acoustically active region AR. As another example, a magnitude of the effective piezoelectric coefficient of the engineered region 24e of the piezoelectric layer 24 can be less than 20% of a magnitude of the effective piezoelectric coefficient of the piezoelectric layer 24 in the acoustically active region AR. As one more example, a magnitude of the effective piezoelectric coefficient of the engineered region 24e of the piezoelectric layer 24 can be less than 10% of a magnitude of the effective piezoelectric coefficient of the piezoelectric layer 24 in the acoustically active region AR. In some applications, the magnitude of the effective piezoelectric coupling coefficient of the piezoelectric layer 24 in the engineered region 24e can be zero or close to zero.

The effective piezoelectric coefficient can be an aggregate piezoelectric coefficient for the entire engineered region 24e. The aggregate magnitude of the piezoelectric polarization vectors in the engineered region 24e should be less than the magnitude in the regular region 24r. The lower magnitude effective piezoelectric coefficient can be a result of the non-aligned nature of piezoelectric material crystal orientations within the engineered region 24e causing a lower aggregate magnitude of the piezoelectric polarization vectors than in the regular region 24r.

The effective piezoelectric coefficient can be an effective piezoelectric coupling coefficient (e₃₃), for example. The engineered region 24e of the piezoelectric layer 24 can suppress the frame mode associated with the raised frame structure 32. BAW devices with an engineered region of a piezoelectric layer and a frame structure (e.g., a raised frame structure 32 and/or a recessed frame structure 34) disclosed herein can enable frame mode suppression, transverse mode suppression, and lateral mode suppression.

A boundary or border between the regular region 24r and the engineered region 24e of the piezoelectric layer 24 can be the boundary or border between the active region AR and the peripheral region PR, respectively. The border between the regular region 24r and the engineered region 24e can be adjusted to have more engineered region area+EPW or less engineered region area −EPW relative to the BAW device 1 shown in FIG. 1A. In FIG. 1B, the +EPW and the −EPW are shown relative to a border of the frame region.

FIGS. 1C-1 to 1C-4 are graphs showing simulated quality factor Qp contours of the BAW device 1 for different recessed frame widths ReW (ReW=1200 nanometers (nm) in FIG. 1C-1, ReW=1800 nm in FIG. 1C-2, ReW=2400 nm in FIG. 1C-3, and ReW=3000 nm in FIG. 1C-4) of the recessed frame structure 34. In FIGS. 1C-1 to 1C-4, the x-axis corresponds to the border between the regular region 24r and the engineered region 24e relative to the border between the active region AR and the frame region in the BAW device 1 of FIG. 1A, and the y-axis corresponds to a recessed frame depth ReD of the recessed structure 34. The dashed lines in the graphs in FIGS. 1C-1 to 1C-4 indicate a preferred combination of the recessed frame depth ReD and the location EPW of the border between the regular region 24r and the engineered region 24e of the piezoelectric layer 24. The simulation results of FIGS. 1C-1 to 1C-4 indicate that the quality factor Qp can be affected by the recessed frame depth ReD and the location EPW of the border between the regular region 24r and the engineered region 24e. However, the quality factor Qp can be more independent from the recessed frame depth ReD than the location EPW of the border between the regular region 24r and the engineered region 24e and the quality factor Qp varies with respect to increasing EPW.

Referring to FIG. 1A, the first electrode 20 can be referred to as a lower electrode. The first electrode 20 can have a relatively high acoustic impedance. The first electrode 20 can include molybdenum (Mo), tungsten (W), ruthenium (Ru), chromium (Cr), iridium (Ir), platinum (Pt), or any suitable alloy and/or combination thereof. Similarly, the second electrode 22 can have a relatively high acoustic impedance. The second electrode 22 can include Mo, W, Ru, Cr, Ir, Pt, or any suitable alloy and/or combination thereof. The second electrode 22 can be formed of the same material as the first electrode 20 in certain applications. The second electrode 22 can be referred to as an upper electrode. The thickness of the first electrode 20 can be approximately the same as the thickness of the second electrode 22 in the acoustically active region AR of the BAW device 1.

The piezoelectric layer 24 can include a suitable material such as, but not limited to, aluminum nitride (AlN), zinc oxide (ZnO), or lead zirconium titanate (PZT). In certain applications, the piezoelectric layer 24 can be an AlN layer. The piezoelectric material can be doped or undoped. For example, an AlN-based piezoelectric layer can be doped with any suitable dopant, such as scandium (Sc), chromium (Cr), magnesium (Mg), sulfur (S), yttrium (Y), silicon (Si), germanium (Ge), oxygen (O), hafnium (Hf), zirconium (Zr), titanium (Ti), or the like. In certain applications, the piezoelectric layer 24 can be AlN based layer doped with Sc. Doping the piezoelectric layer 24 can adjust the resonant frequency. Doping the piezoelectric layer 24 can increase the electromechanical coupling coefficient (kt²) of the BAW device 1. Doping to increase the kt² can be advantageous at higher frequencies where kt² can be degraded. In certain applications, two or more piezoelectric layers can be implemented with any suitable principles and advantages disclosed herein.

The frame structure 31 can be configured to suppress the transverse mode. The raised frame structure 32 can reduce or impede propagation of the transverse mode. As illustrated, the raised frame structure 32 is a multi-layer raised frame structure that includes a raised frame structure 32a and a raised frame structure 32b. The raised frame structure 32b can include a material that has a relatively high mass density. For instance, the raised frame structure 32b can include molybdenum (Mo), tungsten (W), ruthenium (Ru), the like, or any suitable alloy thereof. In some embodiments, the raised frame structure 32b and the second electrode 22 can be formed of a same material. The raised frame structure 32b can be a metal layer. Alternatively, the raised frame structure 32b can be a suitable non-metal material with a relatively high density. The density of the raised frame structure 32b can be similar to or heavier than the density of the first electrode 20 or the second electrode 22. The raised frame structure 32a can include a low acoustic impedance material that has a lower acoustic impedance than the first electrode 20, the second electrode 22, and/or the piezoelectric layer 24. For example, the raised frame structure 32a can include a silicon dioxide (SiO₂) layer, a silicon nitride (SiN) layer, a silicon carbide (SiC) layer, or any other suitable low acoustic impedance layer. The raised frame structure 32a can be a dielectric layer. The raised frame structure 32a can be an oxide layer. For example, the raised frame structure 32 shown in FIG. 1A includes an oxide raised frame structure 32a having a width ORaW, and a metal raised frame structure 32b having a width MRaW between the recessed frame structure 34 and the oxide raised frame structure 32a.

A frame structure can include, for example, a single layer raised frame structure, a multi-layer raised frame structure that includes two or more raised frame layers such as the illustrated raised frame structure 32, a recessed frame structure such as the illustrated recessed frame structure 34, or a combination of a raised frame structure and a recessed frame structure such as the illustrated frame structure 31. As an example, a frame structure can have a multi-layer raised frame structure that includes a relatively high density layer and a relatively low acoustic impedance layer. The low acoustic impedance layer can contribute to reducing an effective kt² relative to a single high-density raised frame structure, which can reduce excitation strength of a raised frame spurious mode. As another example, a floating raised frame structure can be implemented. In the BAW device 1, the frame structure 31 is illustrated as being asymmetric about the acoustically active region AR. However, in some embodiments, the frame structure 31 can be symmetric about the acoustically active region AR.

The support structure 14 can include a support substrate 40 and an intermediate layer 42 between the support substrate and the first electrode 20. The support substrate 40 can be a semiconductor substrate. The support substrate 40 can be a silicon substrate. The support substrate 40 can be any other suitable support substrate, such as a substrate of quartz, silicon carbide, sapphire, glass, gallium arsenide, or any suitable ceramic (e.g., spinel, alumina, etc.).

The intermediate layer 42 can include, for example, one or more of a seed layer, a trap rich layer, a passivation layer, or one or more other suitable functional layers. In some embodiments, the intermediate layer 42 can be completely or partially omitted. In some such embodiments, a portion of the first electrode 20 can directly contact the support substrate 40. The intermediate layer 42 can be relatively thin. For example, the intermediate layer 42 can be significantly thinner than the support substrate 40. Heat generated by the BAW device 1 can dissipate through the first electrode 20 to the support substrate 40 at a location where there is no cavity 18 between the first electrode 20 and the support substrate 40.

As shown in FIG. 1A, a first interconnect structure 16a can include one or more conductive layers such as a first conductive layer 50a and a second conductive layer 52a. Similarly, a second interconnect structure 16b can include one or more conductive layers such as a first conductive layer 50b and a second conductive layer 52b. The first conductive layers 50a, 50b and the second conductive layers 52a, 52b can each include a material suitable for interconnecting the BAW device 1 and one or more other component (e.g., another resonator) in a filter, an external component, or a ground connection. The first conductive layers 50a, 50b and/or the second conductive layers 52a, 52b can be highly electrically conductive. For example, the first conductive layers 50a, 50b and/or the second conductive layers 52a, 52b can be more electrically conductive than the first electrode 20 and/or the second electrode 22. In some embodiments, the first conductive layers 50a, 50b and/or the second conductive layers 52a, 52b can include one or more of gold (Au), titanium (Ti), copper (Cu), aluminum (Al), or tungsten (W).

The cavity 18 (e.g., an air cavity) can be formed between the support substrate 40 and the first electrode 20. The cavity 18 is an example of an acoustic reflector. The BAW device 1 can include a film bulk acoustic wave resonator (FBAR). In some other embodiments, there can be a solid acoustic mirror in place of the cavity 18 and such a BAW device can be a BAW solidly mounted resonator (SMR).

FIG. 2 is a schematic cross-sectional side view of a portion of a BAW device 2 according to an embodiment. Unless otherwise noted, the components of the BAW device 2 shown in FIG. 2 may be structurally and/or functionally the same as or generally similar to like components of other BAW devices disclosed herein. The BAW device 2 can include a support substrate 40, a cavity 18, and an intermediate layer 42, a first electrode 20, a second electrode 22, a piezoelectric layer 24 between the first electrode 20 and the second electrode 22, a passivation layer 26, and a seed layer 64. In some embodiments, the seed layer 64 can be provided by way of deposition. The seed layer 64 may include, for example, atomic layer deposited aluminum nitride (ALD-AlN) layer. The piezoelectric layer 24 includes an engineered region 24e in the peripheral region PR and a regular region 24r in the acoustically active region AR. In FIG. 2, the frame region 31 on one side of the BAW device 2 and a relatively small part of the acoustically active region AR of the BAW device 2 are illustrated.

The first electrode 20 has a first portion 20a having a first thickness t1, and a second portion 20b having a second thickness t2. The seed layer 64 is positioned between the second portion 20a of the first electrode 20 and the engineered region 24e of the piezoelectric layer 24. In the BAW device 1, the seed layer 64 can cause the piezoelectric layer 24 to be engineered in the engineered region 24e. The seed layer 64 can be a material that has poor crystallinity or is crystalline with a poor lattice match to the piezoelectric film applied over the seed layer 64. The piezoelectric layer 24 in the engineered region 24e over the seed layer 64 can have relatively poor bulk piezoelectric properties compared to the piezoelectric layer in the regular region 24r. The seed layer 64 can be directly over the first electrode 20. The seed layer 64 can be an atomic deposition layer, for example. The seed layer 64 can include, but is not limited to, an oxide, a nitride, a carbide, a carbon structure (e.g., graphene or diamond), a boride, or any suitable combination thereof. In certain applications, the seed layer 64 can include one or more of aluminum oxide, silicon, silicon carbide, doped aluminum nitride, undoped aluminum nitride, aluminum, fused silica, boron nitride, diamond, silicon oxycarbide glass, silicon oxynitride glass, boron carbide, graphene, beryllium oxide, gallium nitride, indium nitride, silicon nitride, scandium nitride, or the like. In some embodiments, the seed layer 64 can have a thickness that is in a single digit nanometer range. In some embodiments, the seed layer 64 can have a thickness that is in a range from 10 nanometers to 100 nanometers.

A method of forming the engineered region 24e of the piezoelectric layer 24 can involve selectively forming the seed layer 64 over the engineered region 24e relative to the regular region 24r of the piezoelectric layer 24. Selective seed layer 64 formation can involve removing (e.g., etching) the seed layer 64 from the acoustically active region AR and/or removing (e.g., etching) a mask for forming the seed layer 64 from the active region AR. In some embodiments, during the process of selectively forming the seed layer 64, the first electrode 20 can be etched due to over etching.

The over etching can create a thickness difference (e.g., a third thickness t3) between the first thickness t1 of the first portion 20a and the second thickness t2 of the second portion 20b of the first electrode 20. The second portion 20b can have a greater thickness than the first portion 20a. The second portion 20b can define a metal raised frame structure 32b of the raised frame structure 32. Because the third thickness t3 between the first thickness t1 and the second thickness t2 can cause a mass loading difference of the metal raised frame structure 32b, an additional process of providing a metal layer to form the raised frame structure 32b can be omitted, in some embodiments. Etching of the first electrode 20 in the active region AR can be controlled to create a desired third thickness t3 for the metal raised frame structure 32b. The first electrode 20 can be intentionally over etched to create a desired thickness difference (the third thickness t3) between the first thickness t1 and the second thickness t2. In some embodiments, a thickness of the seed layer 64 can be greater than the third thickness t3. For example, the thickness of the seed layer 64 can be more than 2 times, 3 times, 4 times, or 5 times greater than the third thickness t3. In some embodiments, there may be no over etching and the first and second thicknesses t1, t2 can be the same (e.g., the third thickness t3=0).

The raised frame structure 32 can also include a dielectric raised frame structure (e.g., an oxide raised frame structure 32a). The oxide raised frame structure 32a can be positioned in the peripheral region PR, between the engineered region 24e of the piezoelectric layer 24 and the second electrode 22.

The recessed frame structure 34 can be positioned in the acoustically active region AR of the BAW device 2. A region of the acoustically active region AR that does not include the recessed frame structure 34 and/or that does not overlap the frame region can be referred to as a main acoustically active region MAR. The recessed frame structure 34 can include a recess in the passivation layer 26 that has a depth ReD. The passivation layer can have generally the same thickness in the recessed frame region as in the peripheral region PR in the BAW device 2.

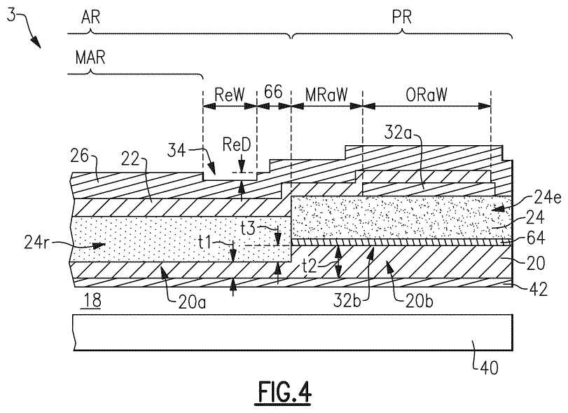

FIG. 3 is a graph showing simulated S 11 results of two different BAW devices, a BAW device A and the BAW device 2 of FIG. 2. Unlike the BAW device 2, the BAW device A includes a recessed frame structure that is positioned outside of an acoustically active region of the BAW device A. In BAW device A, the recessed frame structure is offset from the acoustically active region and formed by thinning a passivation layer over a top electrode. Three simulations were conducted with the BAW device 2. The simulation results of FIG. 3 indicate that with the recessed frame structure positioned in the acoustically active region AR in the BAW device 2, the lateral mode can be significantly suppressed compared to the BAW device A. The electromechanical coupling coefficient kt² of the BAW device 2 and the BAW device A can be generally similar. The quality factor Qp of the BAW device 2 may degrade slightly.

FIG. 4 is a schematic cross-sectional side view of a portion of a BAW device 3 according to an embodiment. In FIG. 4, the frame region 31 on one side of the BAW device 3 and a relatively small part of the acoustically active region AR of the BAW device 3 are illustrated. Unless otherwise noted, the components of the BAW device 3 shown in FIG. 4 may be structurally and/or functionally the same as or generally similar to like components of other BAW devices disclosed herein. The BAW device 3 is generally similar to the BAW device 2 of FIG. 2 except that the BAW device 3 (1) includes a spacing 66 between the recessed frame structure 34 and the raised frame structure 32 and (2) the passivation layer 26 has generally the same thickness in the peripheral region PR as in the main acoustically active region MAR. The spacing 66 offsets the raised frame structure 32 from the recessed frame structure 34. The spacing 66 can be referred to as an offset. The spacing 66 can compensate for the potential misalignment between the recessed frame structure 34 and the engineered region 24e of the piezoelectric layer 24. In manufacturing the BAW device 3, the passivation layer 26 can be etched only in a recessed frame region.

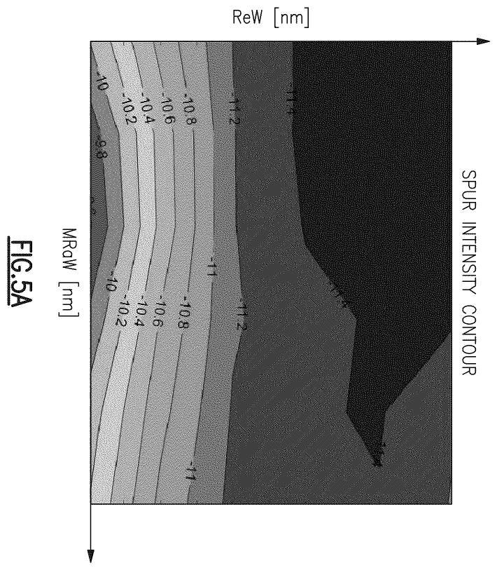

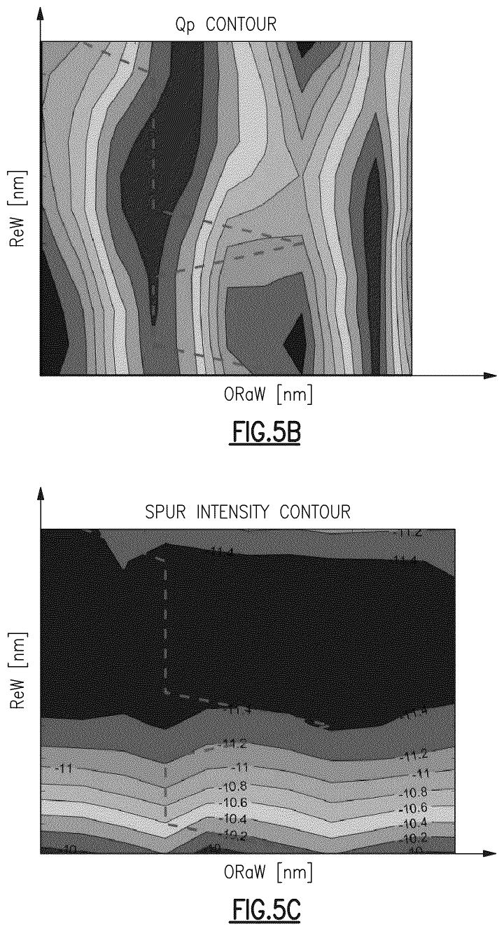

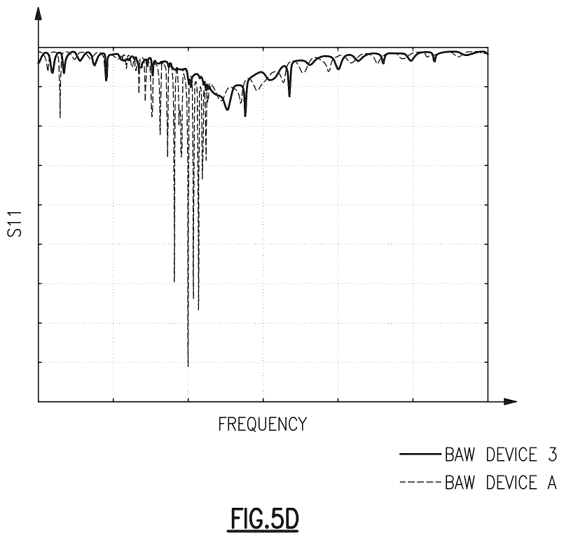

FIG. 5A is a simulated spur intensity contour map of the BAW device 3 of FIG. 4. The spur intensity contour map of FIG. 5A shows a width MraW of the metal raised frame structure 32b on the x-axis and the width ReW of the recessed frame structure 34 on the y-axis. FIG. 5B is a simulated quality factor Qp contour map of the BAW device 3 of FIG. 4. The quality factor Qp contour map of FIG. 5B shows a width OraW of the oxide raised frame structure 32a on the x-axis and the width ReW of the recessed frame structure 34 on the y-axis. FIG. 5C is another simulated spur intensity contour map of the BAW device 3 of FIG. 4. The spur intensity contour map of FIG. 5C shows a width OraW of the oxide raised frame structure 32a on the x-axis and the width ReW of the recessed frame structure 34 on the y-axis. FIG. 5D is a graph showing simulated S 11 results of two different BAW devices, the BAW device A used in the simulation of FIG. 2 and the BAW device 3 of FIG. 4.

The simulation results indicate that forming the recessed frame structure 34, such as the recess or notch formed in the passivation layer 26, in the acoustically active region AR can significantly attenuate the lateral modes. The lateral mode intensity can be affected by the width ReW of the recessed frame structure 34 more than the spacing 66 between the recessed frame structure 34 and the raised frame structure 32. In some instances, lateral mode attenuation can be primarily (or only) a function of the width of the ReW of the recessed frame structure. The quality factor Qp of the BAW device 3 can be greater than the BAW device A, and can be maintained at a generally constant level despite the variations in the widths of the raised frame structure 32 and/or the recessed frame structure 34. Also, the width MRaW of the metal raised frame structure 32b and the width ReW of the recessed frame structure 34 may not significantly affect the quality factor Qp. The width MRaW of the metal raised frame structure 32b and the width ORaW of the recessed frame structure 34 may not significantly affect the lateral mode behavior. Further, optimized conditions for lateral mode suppression and the quality factor Q can be orthogonal to each other.

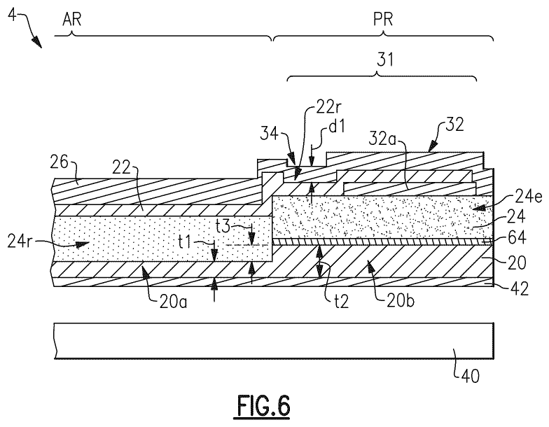

FIG. 6 is a schematic cross-sectional side view of a portion of a BAW device 4 according to an embodiment. In FIG. 6, the frame region 31 on one side of the BAW device 4 and a relatively small part of the acoustically active region AR of the BAW device 4 are illustrated. Unless otherwise noted, the components of the BAW device 4 shown in FIG. 6 may be structurally and/or functionally the same as or generally similar to like components of other BAW devices disclosed herein. Unlike the BAW devices 2 and 3 of FIGS. 2 and 4, respectively, the BAW device 4 the thickness of passivation layer 26 is generally constant in the acoustically active region AR. The passivation layer 26 is free from a recess in the acoustically active region AR that defines a recessed frame structure. The BAW device 4 includes a metal recessed frame structure as an example of the recessed frame structure 34. The metal recessed frame structure includes a recess 22r in the second electrode 22. The recess 22r has a depth d1. In the BAW device 4, the recessed frame structure 34 is located in the peripheral region PR.

The second portion 20b of the first electrode 20 can overlap the recess 22r in the second electrode 22. When the depth d1 of the recess 22r in the second electrode 22 is greater than the thickness difference (the third thickness t3) between the first thickness t1 and the second thickness t2 of the first electrode, the recess 22r in the second electrode 22 can define the recessed frame structure 34. When the third thickness t3 is greater than the depth d1, the second portion 20b can provide a metal raised frame structure between the oxide raised frame structure 32a and recess 22r. A skilled artisan will understand that when the mass densities of the first electrode 20 and the second electrode 22 are different, the mass loading effect may not directly be translated from the thickness difference between the third thickness t3 and the depth d1.

A material of the second electrode 22 can have a higher mass density than a material used of the passivation layer 26. Therefore, the same change in mass loading can be achieved with a smaller and/or shallower recess in the second electrode 22 than in the passivation layer 26, or the same recessed depth for the same area can provide a greater change in mass loading by the second electrode 22 than the passivation layer 26. In some embodiments, the recess 22r in the second electrode 22 can be more desirable than the recess in the passivation layer 26 for lateral mode suppression. For example, implementation of the recess 22r or a metal recessed frame structure as the recessed frame structure 34 can be particularly beneficial for ultra-high band (UHB) applications.

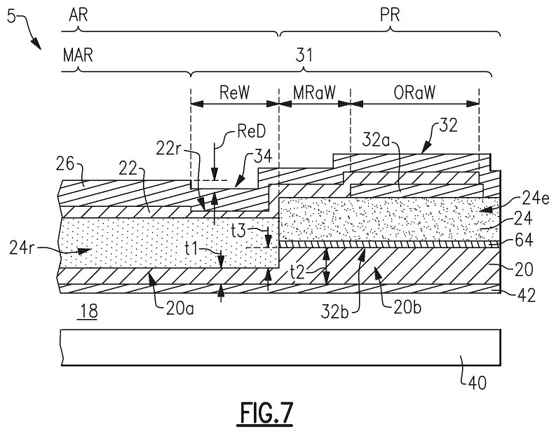

FIG. 7 is a schematic cross-sectional side view of a portion of a BAW device 5 according to an embodiment. In FIG. 7, the frame region 31 on one side of the BAW device 5 and a relatively small part of the acoustically active region AR of the BAW device 5 are illustrated. Unless otherwise noted, the components of the BAW device 5 shown in FIG. 7 may be structurally and/or functionally the same as or generally similar to like components of other BAW devices disclosed herein. The BAW device 5 can be generally similar to the BAW device 2 of FIG. 2, except for the recessed frame structure 34. In place of or in addition to the recess in the passivation layer 26, the BAW device 5 includes a recess 22r in the second electrode 22 as the recessed frame structure 34. For example, as illustrated in FIG. 7, a recess 22r in the second electrode is the recessed frame structure 34. In the BAW device 5, the recess 22r is in the acoustically active region AR. By controlling the over etch of the first electrode 20 of the BAW device 5, at least part of a raised frame structure can formed by controlling a thickness difference (e.g., a third thickness t3) between the first thickness t1 of the first portion 20a and the second thickness t2 of the second portion 20b of the first electrode 2

FIG. 8 is a schematic cross-sectional side view of a portion of a BAW device 6 according to an embodiment. In FIG. 8, the frame region 31 on one side of the BAW device 6 and a relatively small part of the acoustically active region AR of the BAW device 6 are illustrated. Unless otherwise noted, the components of the BAW device 6 shown in FIG. 8 may be structurally and/or functionally the same as or generally similar to like components of other BAW devices disclosed herein. The BAW device 6 can be generally similar to the BAW device 5 of FIG. 7 except for the recessed frame structure 34. In place of or in addition to the recess 22r in the second electrode 22, the BAW device 6 includes a third portion 20c of the first electrode 20 that has a thickness t4 smaller than the thickness t1 of the first portion 20a. A thickness difference (e.g., a fifth thickness t5) between the first thickness t1 and the fourth thickness t4 can define at least a portion of the recessed frame structure 34.

The first portion 20a of the first electrode 20 is in the main acoustically active region MAR, the second portion 20b of the first electrode 20 is in the peripheral region PR, and the third portion 20c of the first electrode 20 is in the acoustically active region AR but outside of the main acoustically active region MAR. In some embodiments, when in a selective seed layer formation process, the first electrode 20 can be selectively etched more at the third portion 20c than the first portion 20a to create the thickness difference (the fifth thickness t5) between the first thickness t1 and the fourth thickness t4.

Any suitable combination(s) of the features disclosed herein can be implemented in a BAW device. For example, a BAW device can include any suitable combination of an oxide recessed frame structure formed with a passivation layer, a metal recessed frame structure formed with a first electrode, and/or a metal recessed frame structure formed with a second electrode. The portions of the BAW devices 2, 3, 4, 5, 6 shown FIGS. 2, 4, 6, 7, 8, respectively, can have an overall structure, for example, similar to the BAW device 1 shown in FIG. 1A in which the first electrode 20 is coupled to the first interconnect structure 16a and the second electrode 22 is coupled to the second interconnect structure 16b.

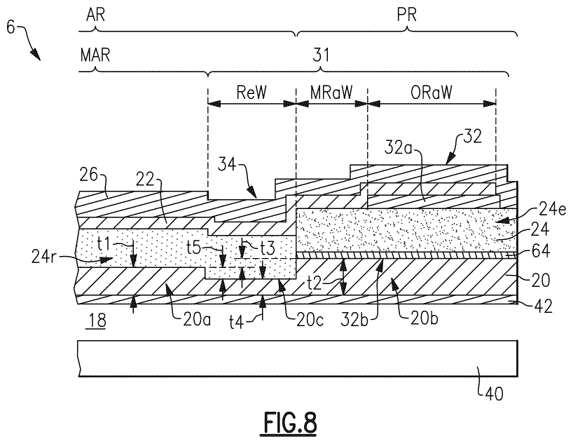

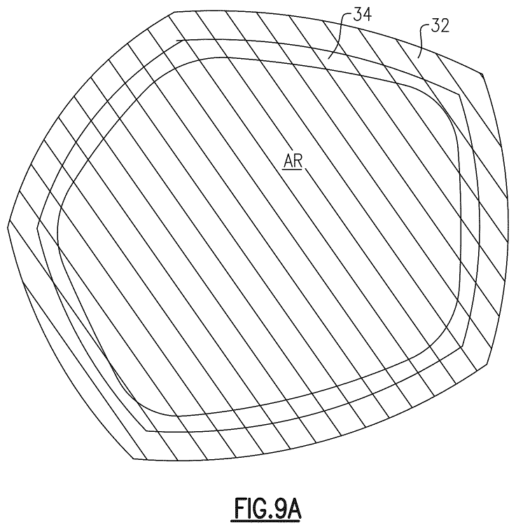

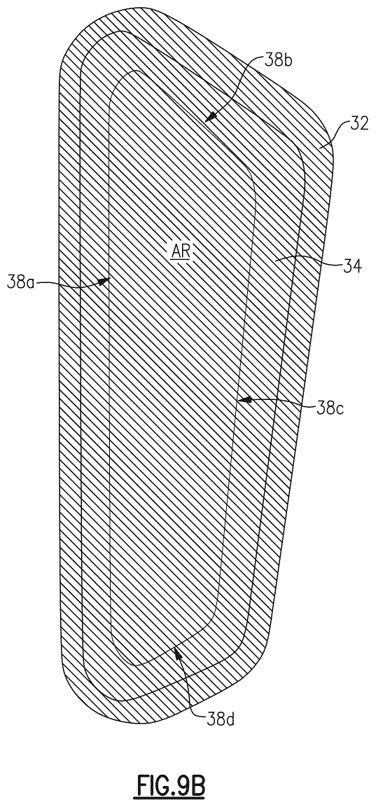

FIG. 9A is an example schematic top plan view of a BAW device. In FIG. 9A, the acoustically active region AR can be at least partially (e.g., fully) surrounded by a raised frame structure 32. A recessed frame structure 34 can be included within the acoustically active region AR around the outer perimeter of the acoustically acoustic region AR. In some other embodiments, a recessed frame structure 34 can be included outside of and around the acoustically active region AR. As illustrated, the active region AR can correspond to the majority of the area of the BAW device. FIG. 9A illustrates the BAW device with a pentagon shape with curved sides in plan view. A BAW device in accordance with any suitable principles and advantages disclosed herein can have any other suitable shape in plan view, such as a semi-elliptical shape, a semi-circular shape, a circular shape, an ellipsoid shape, a quadrilateral shape, or a quadrilateral shape with curved sides.

FIG. 9B is another example plan view of a BAW device. The plan view of FIG. 9B can have an irregular quadrilateral shape. The shape of the plan view shown in FIG. 9B can be implemented in any suitable BAW devices disclosed herein. In FIG. 9B, the acoustically active region AR can be at least partially (e.g., fully or partially) surrounded a raised frame structure 32. A recessed frame structure 34 can at least partially (e.g., fully or partially) surround the acoustically active region. In some other embodiments, a recessed frame structure 34 can be included in the acoustically active region AR around a perimeter of the acoustically active region AR. The acoustically active region AR can have a first side 38a, a second side 38b, a third side 38c, a fourth side 38d, and rounded corners therebetween. The first side 38a can be the longest side. The first side 38a and the third side 38c can be significantly longer than the second side 38b and the fourth side 38d. For example, the first side 38a and/or the third side 38c can be more than twice or triple the length of the second side 38b or the fourth side 38d. An outer periphery of a frame region that includes the recessed frame structure 34 and the raised frame structure 34 can have a generally similar shape as a main acoustically active region that is free from the frame structures.

In some applications, the recessed frame structure 34 and the raised frame structure 32 can be spaced by a gap in a plan view. The recessed frame structure 34 and the raised frame structure 32 can be arranged in any suitable manner. In some applications, the shape of FIG. 9B can reduce lateral mode and increase the quality factor Qs as compared to the shape of FIG. 9A.

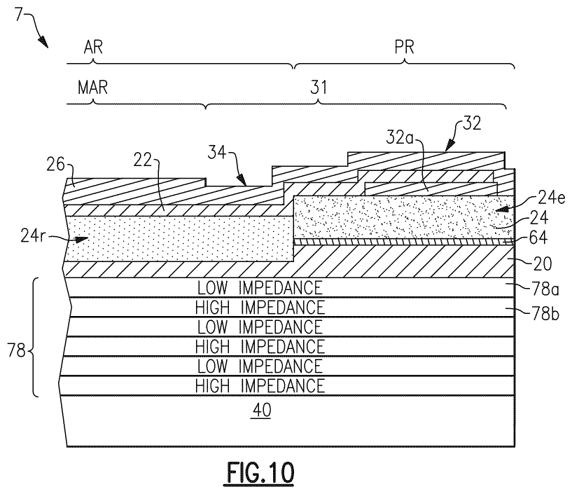

FIG. 10 is an example of a BAW solidly mounted resonator (SMR) 7 according to an embodiment. FIG. 11 is an example of a BAW SMR 8 according to another embodiment. Unless otherwise noted, the components of the BAW SMRs 7, 8 shown in FIGS. 10 and 11 may be structurally and/or functionally the same as or generally similar to like components of other BAW devices disclosed herein. In the BAW SMR 7, the recessed frame structure 34 is included in the acoustically active region AR. In the BAW SMR 8, the recessed frame structure 34 is included in the peripheral region PR. In place of the cavity 18 shown in one or more other figures, the BAW SMRs 7, 8 include a solid acoustic mirror 78 between the support substrate 40 and the first electrode 20. The illustrated acoustic mirror 78 includes acoustic Bragg reflectors. The illustrated acoustic Bragg reflectors can include alternating low impedance layers 78a and high impedance layers 78b. As an example, the Bragg reflectors can include alternating silicon dioxide layers as low impedance layers 78a and tungsten layers as high impedance layers 78b. Any other suitable features of an SMR can alternatively or additionally be implemented. Any other suitable features of BAW devices disclosed herein can be implemented in a BAW SMR.

BAW devices disclosed herein can be implemented in a variety of applications. Applications of these BAW devices include, but are not limited to, a BAW resonator for filter that filters an electrical signal, a BAW oscillator such as a BAW oscillator for a clock generator, a BAW sensor (e.g., a gas sensor, a particle sensor, a mass sensor, a pressure or touch sensor, etc.), a BAW delay line such as BAW delay line for radar and/or instrumentation applications, an actuator, a microphone, and a speaker. Filters that include BAW resonators can be implemented in a variety of applications including, but not limited to, mobile phones, mobile computing devices, base stations, repeaters, relays, wireless communication infrastructure, access points, customer premises equipment (CPE), and distributed antenna systems. BAW oscillators can replace crystal oscillators in a variety of applications, such as but not limited to electronic timing products.

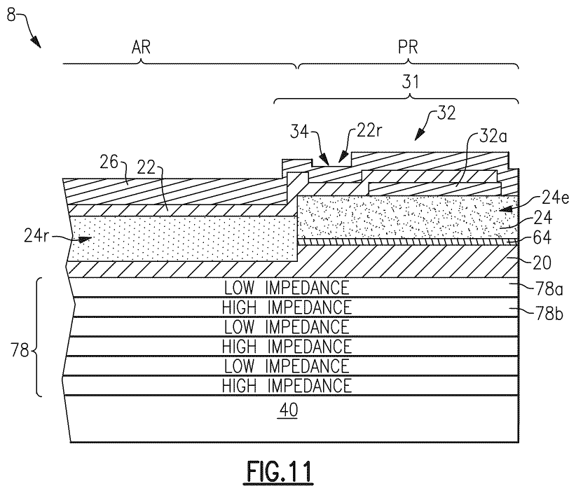

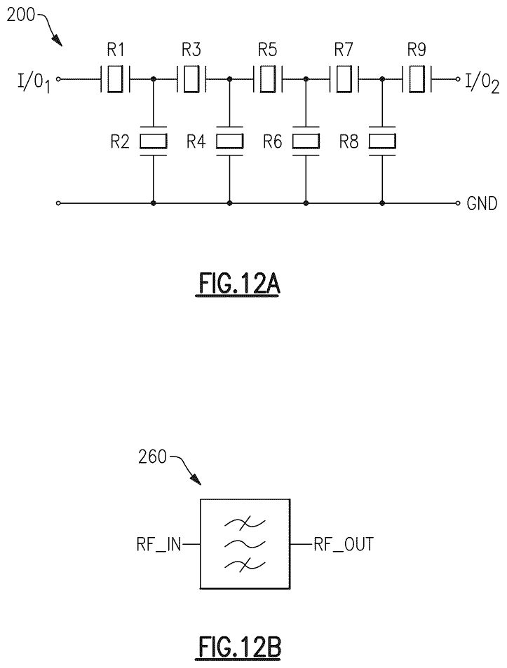

BAW devices disclosed herein can be implemented as BAW resonators in a variety of filters. Such filters can be arranged to filter a radio frequency signal. BAW devices disclosed herein can be implemented in a variety of different filter topologies. Example filter topologies include without limitation, ladder filters, lattice filters, hybrid ladder lattice filters, notch filters where a notch is created by an acoustic wave resonator, hybrid acoustic and non-acoustic inductor-capacitor filters, and the like. The example filter topologies can implement band pass filters. The example filter topologies can implement band stop filters. In some instances, acoustic wave devices disclosed herein can be implemented in filters with one or more other types of resonators and/or with passive impedance elements, such as one or more inductors and/or one or more capacitors. An example filter topology will be discussed with reference to FIG. 12A.

FIG. 12A is a schematic diagram of a ladder filter 200 that includes a BAW resonator according to an embodiment. The ladder filter 200 is an example topology that can implement a band pass filter formed of acoustic wave resonators. In a band pass filter with a ladder filter topology, the shunt resonators can have lower resonant frequencies than the series resonators. The ladder filter 200 can be arranged to filter a radio frequency signal. As illustrated, the ladder filter 200 includes series acoustic wave resonators R1 R3, R5, R7, and R9 and shunt acoustic wave resonators R2, R4, R6, and R8 coupled between a first input/output port I/O₁ and a second input/output port I/O₂. Any suitable number of series acoustic wave resonators can be included in a ladder filter. Any suitable number of shunt acoustic wave resonators can be included in a ladder filter. The first input/output port I/O₁ can be a transmit port and the second input/output port I/O₂ can be an antenna port. Alternatively, the first input/output port I/O₁ can be a receive port and the second input/output port I/O₂ can be an antenna port. One or more of the acoustic wave resonators of the ladder filter 200 can include a BAW resonator in accordance with any suitable principles and advantages disclosed herein. All acoustic resonators of the ladder filter 200 can include a BAW resonator in accordance with any suitable principles and advantages disclosed herein.

A filter that includes a BAW resonator in accordance with any suitable principles and advantages disclosed herein be arranged to filter a radio frequency signal in a fifth generation 5G NR operating band within Frequency Range 1 (FR1). FR1 can be from 410 MHz to 7.125 gigahertz (GHz), for example, as specified in a current 5GNNR specification. A filter that includes a BAW resonator in accordance with any suitable principles and advantages disclosed herein can be arranged to filter a radio frequency signal in a fourth generation (4G) Long Term Evolution (LTE) operating band. A filter that includes a BAW resonator in accordance with any suitable principles and advantages disclosed herein can be included in a filter having a passband that includes a 4G LTE operating band and a 5G NR operating band. Such a filter can be implemented in a dual connectivity application, such as an E-UTRAN New Radio-Dual Connectivity (ENDC) application. A multiplexer including any such filters can include one or more other filters with a passband corresponding to a 5G NR operating band and/or a 4G LTE operating band. A filter that includes a BAW resonator in accordance with any suitable principles and advantages disclosed herein can be arranged to filter a radio frequency signal in any other suitable operating band, such as a WiFi operating band or a Global Positioning System (GPS) operating band.

The BAW resonators disclosed herein can be advantageous for implementing BAW devices with relatively high Qp and relatively low spur intensity. BAW resonators disclosed herein can have significantly better performance than a variety of other BAW resonators. This can be advantageous in meeting demanding specifications for acoustic wave filters, such as performance specifications for certain 5G applications.

FIG. 12B is schematic diagram of an acoustic wave filter 260. The acoustic wave filter 260 can include the acoustic wave resonators of the ladder filter 200. The acoustic wave filter 260 is a band pass filter. The acoustic wave filter 260 is arranged to filter a radio frequency signal. The acoustic wave filter 260 includes one or more acoustic wave devices coupled between a first input/output port RF_IN and a second input/output port RF_OUT. The acoustic wave filter 260 includes a BAW resonator according to an embodiment.

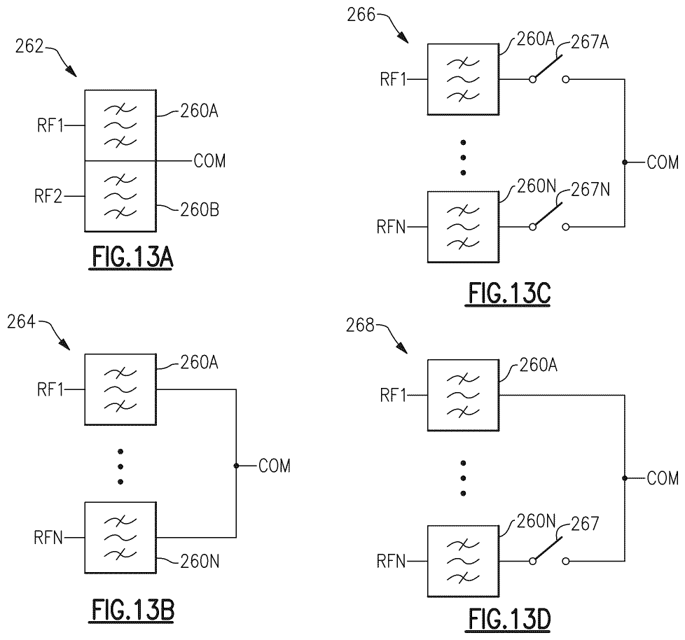

The BAW devices disclosed herein can be implemented in a standalone filter and/or in a filter of any suitable multiplexer. Such filters can be any suitable topology, such as a ladder filter topology. The filter can be a band pass filter arranged to filter a 4G LTE band and/or 5G NR band. Example multiplexers will be discussed with reference to FIGS. 13A to 13D. Any suitable principles and advantages of these multiplexers can be implemented together with each other.

FIG. 13A is a schematic diagram of a duplexer 262 that includes an acoustic wave filter according to an embodiment. The duplexer 262 includes a first filter 260A and a second filter 260B coupled together at a common node COM. One of the filters of the duplexer 262 can be a transmit filter and the other of the filters of the duplexer 262 can be a receive filter. In some other instances, such as in a diversity receive application, the duplexer 262 can include two receive filters. Alternatively, the duplexer 262 can include two transmit filters. The common node COM can be an antenna node.

The first filter 260A is an acoustic wave filter arranged to filter a radio frequency signal. The first filter 260A includes one or more acoustic wave resonators coupled between a first radio frequency node RF1 and the common node COM. The first radio frequency node RF1 can be a transmit node or a receive node. The first filter 260A includes a BAW resonator in accordance with any suitable principles and advantages disclosed herein.

The second filter 260B can be any suitable filter arranged to filter a second radio frequency signal. The second filter 260B can be, for example, an acoustic wave filter, an acoustic wave filter that includes a BAW resonator in accordance with any suitable principles and advantages disclosed herein, an LC filter, a hybrid acoustic wave LC filter, or the like. The second filter 260B is coupled between a second radio frequency node RF2 and the common node. The second radio frequency node RF2 can be a transmit node or a receive node.

Although example embodiments may be discussed with filters or duplexers for illustrative purposes, any suitable principles and advantages disclosed herein can be implement in a multiplexer that includes a plurality of filters coupled together at a common node. Examples of multiplexers include but are not limited to a duplexer with two filters coupled together at a common node, a triplexer with three filters coupled together at a common node, a quadplexer with four filters coupled together at a common node, a hexaplexer with six filters coupled together at a common node, an octoplexer with eight filters coupled together at a common node, or the like. Multiplexers can include filters having different passbands. Multiplexers can include any suitable number of transmit filters and any suitable number of receive filters. For example, a multiplexer can include all receive filters, all transmit filters, or one or more transmit filters and one or more receive filters. One or more filters of a multiplexer can include any suitable number of acoustic wave devices in accordance with any suitable principles and advantages disclosed herein.

FIG. 13B is a schematic diagram of a multiplexer 264 that includes an acoustic wave filter according to an embodiment. The multiplexer 264 includes a plurality of filters 260A to 260N coupled together at a common node COM. The plurality of filters can include any suitable number of filters including, for example, 3 filters, 4 filters, 5 filters, 6 filters, 7 filters, 8 filters, or more filters. Some or all of the plurality of acoustic wave filters can be acoustic wave filters. As illustrated, the filters 260A to 260N each have a fixed electrical connection to the common node COM. This can be referred to as hard multiplexing or fixed multiplexing. Filters have fixed electrical connections to the common node in hard multiplexing applications.

The first filter 260A is an acoustic wave filter arranged to filter a radio frequency signal. The first filter 260A can include one or more acoustic wave devices coupled between a first radio frequency node RF1 and the common node COM. The first radio frequency node RF1 can be a transmit node or a receive node. The first filter 260A includes a BAW resonator in accordance with any suitable principles and advantages disclosed herein. The other filter(s) of the multiplexer 264 can include one or more acoustic wave filters, one or more acoustic wave filters that include a BAW resonator in accordance with any suitable principles and advantages disclosed herein, one or more LC filters, one or more hybrid acoustic wave LC filters, the like, or any suitable combination thereof.

FIG. 13C is a schematic diagram of a multiplexer 266 that includes an acoustic wave filter according to an embodiment. The multiplexer 266 is like the multiplexer 264 of FIG. 13B, except that the multiplexer 266 implements switched multiplexing. In switched multiplexing, a filter is coupled to a common node via a switch. In the multiplexer 266, the switches 267A to 267N can selectively electrically connect respective filters 260A to 260N to the common node COM. For example, the switch 267A can selectively electrically connect the first filter 260A the common node COM via the switch 267A. Any suitable number of the switches 267A to 267N can electrically a respective filter 260A to 260N to the common node COM in a given state. Similarly, any suitable number of the switches 267A to 267N can electrically isolate a respective filter 260A to 260N to the common node COM in a given state. The functionality of the switches 267A to 267N can support various carrier aggregations.

FIG. 13D is a schematic diagram of a multiplexer 268 that includes an acoustic wave filter according to an embodiment. The multiplexer 268 illustrates that a multiplexer can include any suitable combination of hard multiplexed and switched multiplexed filters. One or more acoustic wave devices in accordance with any suitable principles and advantages disclosed herein can be included in a filter (e.g., the filter 260A) that is hard multiplexed to the common node COM of the multiplexer 268. Alternatively or additionally, one or more acoustic wave devices in accordance with any suitable principles and advantages disclosed herein can be included in a filter (e.g., the filter 260N) that is switch multiplexed to the common node COM of the multiplexer 268.

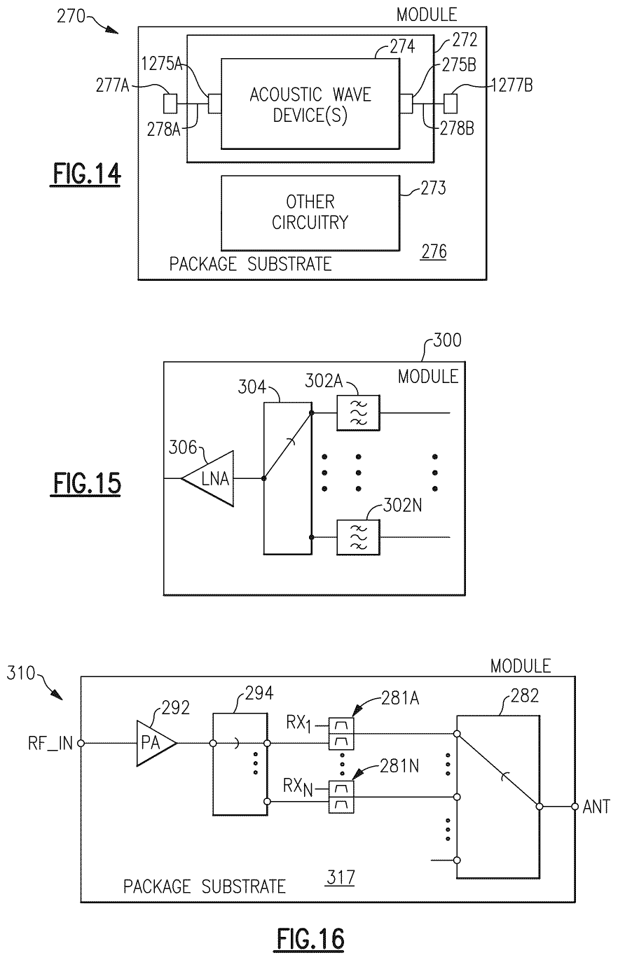

Acoustic wave devices disclosed herein can be implemented in a variety of packaged modules. Some example packaged modules will now be disclosed in which any suitable principles and advantages of the BAW devices disclosed herein can be implemented. The example packaged modules can include a package that encloses the illustrated circuit elements. A module that includes a radio frequency component can be referred to as a radio frequency module. The illustrated circuit elements can be disposed on a common packaging substrate. The packaging substrate can be a laminate substrate, for example. FIGS. 14, 15, and 16 are schematic block diagrams of illustrative packaged modules according to certain embodiments. Any suitable combination of features of these packaged modules can be implemented with each other.

FIG. 14 is a schematic diagram of a radio frequency module 270 that includes an acoustic wave component 272 according to an embodiment. The illustrated radio frequency module 270 includes the acoustic wave component 272 and other circuitry 273. The acoustic wave component 272 can include an acoustic wave filter that includes a plurality of acoustic wave devices, for example. The acoustic wave devices can be BAW devices in certain applications.

The acoustic wave component 272 shown in FIG. 14 includes one or more acoustic wave devices 274 and terminals 275A and 275B. The one or more acoustic wave devices 274 include one or more BAW devices implemented in accordance with any suitable principles and advantages disclosed herein. The terminals 275A and 274B can serve, for example, as an input contact and an output contact. Although two terminals are illustrated, any suitable number of terminals can be implemented for a particular application. The acoustic wave component 272 and the other circuitry 273 are on a common packaging substrate 276 in FIG. 14. The packaging substrate 276 can be a laminate substrate. The terminals 275A and 275B can be electrically connected to contacts 277A and 277B, respectively, on the packaging substrate 276 by way of electrical connectors 278A and 278B, respectively. The electrical connectors 278A and 278B can be bumps or wire bonds, for example.

The other circuitry 273 can include any suitable additional circuitry. For example, the other circuitry can include one or more radio frequency amplifiers (e.g., one or more power amplifiers and/or one or more low noise amplifiers), one or more radio frequency switches, one or more additional filters, one or more RF couplers, one or more delay lines, one or more phase shifters, the like, or any suitable combination thereof. Accordingly, the other circuitry 273 can include one or more radio frequency circuit elements. The other circuitry 273 can be electrically connected to the one or more acoustic wave devices 274. The radio frequency module 270 can include one or more packaging structures to, for example, provide protection and/or facilitate easier handling of the radio frequency module 270. Such a packaging structure can include an overmold structure formed over the packaging substrate 276. The overmold structure can encapsulate some or all of the components of the radio frequency module 270.

FIG. 15 is a schematic block diagram of a module 300 that includes filters 302A to 302N, a radio frequency switch 304, and a low noise amplifier 306 according to an embodiment. One or more filters of the filters 302A to 302N can include any suitable number of bulk acoustic wave devices in accordance with any suitable principles and advantages disclosed herein. Any suitable number of filters 302A to 302N can be implemented. The illustrated filters 302A to 302N are receive filters. One or more of the filters 302A to 302N can be included in a multiplexer that also includes a transmit filter and/or another receive filter. The radio frequency switch 304 can be a multi-throw radio frequency switch. The radio frequency switch 304 can electrically couple an output of a selected filter of filters 302A to 302N to the low noise amplifier 306. In some embodiments, a plurality of low noise amplifiers can be implemented. The module 300 can include diversity receive features in certain applications.

FIG. 16 is a schematic diagram of a radio frequency module 310 that includes an acoustic wave filter according to an embodiment. As illustrated, the radio frequency module 310 includes duplexers 316A to 316N, a power amplifier 312, a radio frequency switch 314 configured as a select switch, and an antenna switch 318. The radio frequency module 310 can include a package that encloses the illustrated elements. The illustrated elements can be disposed on a common packaging substrate 317. The packaging substrate 317 can be a laminate substrate, for example. A radio frequency module that includes a power amplifier can be referred to as a power amplifier module. A radio frequency module can include a subset of the elements illustrated in FIG. 16 and/or additional elements. The radio frequency module 310 may include any one of the acoustic wave filters that include at least one bulk acoustic wave resonator in accordance with any suitable principles and advantages disclosed herein.

The duplexers 316A to 316N can each include two acoustic wave filters coupled to a common node. For example, the two acoustic wave filters can be a transmit filter and a receive filter. As illustrated, the transmit filter and the receive filter can each be a band pass filter arranged to filter a radio frequency signal. One or more of the transmit filters can include a BAW device in accordance with any suitable principles and advantages disclosed herein. Similarly, one or more of the receive filters can include a BAW device in accordance with any suitable principles and advantages disclosed herein. Although FIG. 16 illustrates duplexers, any suitable principles and advantages disclosed herein can be implemented in other multiplexers (e.g., quadplexers, hexaplexers, octoplexers, etc.) and/or in switched multiplexers and/or with standalone filters.

The power amplifier 312 can amplify a radio frequency signal. The illustrated radio frequency switch 314 is a multi-throw radio frequency switch. The radio frequency switch 314 can electrically couple an output of the power amplifier 312 to a selected transmit filter of the transmit filters of the duplexers 316A to 316N. In some instances, the radio frequency switch 314 can electrically connect the output of the power amplifier 312 to more than one of the transmit filters. The antenna switch 318 can selectively couple a signal from one or more of the duplexers 316A to 316N to an antenna port ANT. The duplexers 316A to 316N can be associated with different frequency bands and/or different modes of operation (e.g., different power modes, different signaling modes, etc.).

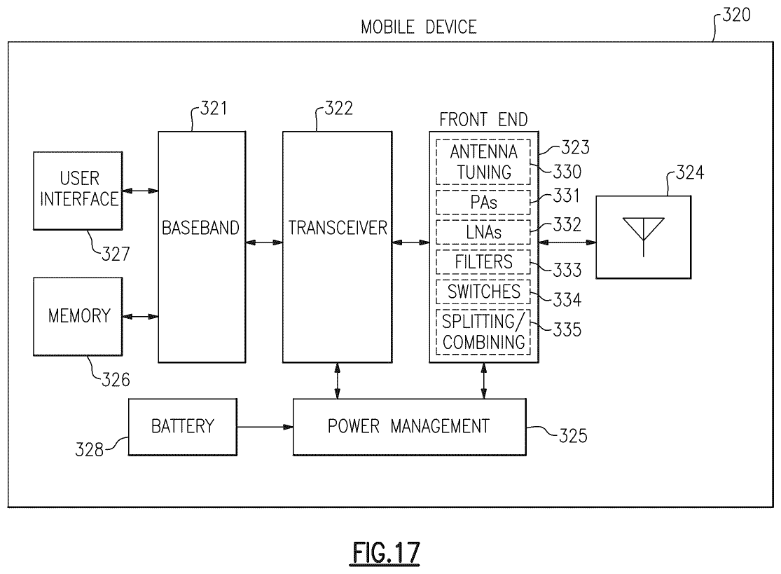

The BAW devices disclosed herein can be implemented in wireless communication devices. FIG. 17 is a schematic block diagram of a wireless communication device 320 that includes a BAW device according to an embodiment. The wireless communication device 320 can be a mobile device. The wireless communication device 320 can be any suitable wireless communication device. For instance, a wireless communication device 320 can be a mobile phone, such as a smart phone. As illustrated, the wireless communication device 320 includes a baseband system 321, a transceiver 322, a front end system 323, one or more antennas 324, a power management system 325, a memory 326, a user interface 327, and a battery 328.

The wireless communication device 320 can be used communicate using a wide variety of communications technologies, including, but not limited to, 2G, 3G, 4G (including LTE, LTE-Advanced, and/or LTE-Advanced Pro), 5G NR, WLAN (for instance, Wi-Fi), WPAN (for instance, Bluetooth and/or ZigBee), WMAN (for instance, WiMax), and/or GPS technologies.

The transceiver 322 generates RF signals for transmission and processes incoming RF signals received from the antennas 324. Various functionalities associated with the transmission and receiving of RF signals can be achieved by one or more components that are collectively represented in FIG. 17 as the transceiver 322. In one example, separate components (for instance, separate circuits or dies) can be provided for handling certain types of RF signals.

The front end system 323 aids in conditioning signals provided to and/or received from the antennas 324. In the illustrated embodiment, the front end system 323 includes antenna tuning circuitry 330, power amplifiers (PAs) 331, low noise amplifiers (LNAs) 332, filters 333, switches 334, and signal splitting/combining circuitry 335. However, other implementations are possible. The filters 333 can include one or more acoustic wave filters that include any suitable number of BAW devices in accordance with any suitable principles and advantages disclosed herein.

For example, the front end system 323 can provide a number of functionalities, including, but not limited to, amplifying signals for transmission, amplifying received signals, filtering signals, switching between different bands, switching between different power modes, switching between transmission and receiving modes, duplexing of signals, multiplexing of signals, or any suitable combination thereof.

In certain implementations, the wireless communication device 320 supports carrier aggregation, thereby providing flexibility to increase peak data rates. Carrier aggregation can be used for Frequency Division Duplexing (FDD) and/or Time Division Duplexing (TDD), and may be used to aggregate a plurality of carriers and/or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 324 can include antennas used for a wide variety of types of communications. For example, the antennas 324 can include antennas for transmitting and/or receiving signals associated with a wide variety of frequencies and communications standards.

In certain implementations, the antennas 324 support MIMO communications and/or switched diversity communications. For example, MIMO communications use multiple antennas for communicating multiple data streams over a single radio frequency channel. MIMO communications benefit from higher signal to noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal strength indicator.

The wireless communication device 320 can operate with beamforming in certain implementations. For example, the front end system 323 can include amplifiers having controllable gain and phase shifters having controllable phase to provide beam formation and directivity for transmission and/or reception of signals using the antennas 324. For example, in the context of signal transmission, the amplitude and phases of the transmit signals provided to the antennas 324 are controlled such that radiated signals from the antennas 324 combine using constructive and destructive interference to generate an aggregate transmit signal exhibiting beam-like qualities with more signal strength propagating in a given direction. In the context of signal reception, the amplitude and phases are controlled such that more signal energy is received when the signal is arriving to the antennas 324 from a particular direction. In certain implementations, the antennas 324 include one or more arrays of antenna elements to enhance beamforming.

The baseband system 321 is coupled to the user interface 327 to facilitate processing of various user input and output (I/O), such as voice and data. The baseband system 321 provides the transceiver 322 with digital representations of transmit signals, which the transceiver 322 processes to generate RF signals for transmission. The baseband system 321 also processes digital representations of received signals provided by the transceiver 322. As shown in FIG. 17, the baseband system 321 is coupled to the memory 326 of facilitate operation of the wireless communication device 320.

The memory 326 can be used for a wide variety of purposes, such as storing data and/or instructions to facilitate the operation of the wireless communication device 220 and/or to provide storage of user information.

The power management system 325 provides a number of power management functions of the wireless communication device 320. In certain implementations, the power management system 325 includes a PA supply control circuit that controls the supply voltages of the power amplifiers 331. For example, the power management system 325 can be configured to change the supply voltage(s) provided to one or more of the power amplifiers 331 to improve efficiency, such as power added efficiency (PAE).

As shown in FIG. 17, the power management system 325 receives a battery voltage from the battery 328. The battery 328 can be any suitable battery for use in the wireless communication device 320, including, for example, a lithium-ion battery.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes example embodiments, the teachings described herein can be applied to a variety of structures. Any of the principles and advantages discussed herein can be implemented in association with RF circuits configured to process signals having a frequency in a range from about 30 kHz to 300 GHz, such as in a frequency range from about 400 MHz to 8.5 GHz, in FR1, in a frequency range from about 2 GHz to 10 GHz, in a frequency range from about 2 GHz to 15 GHz, or in a frequency range from 5 GHz to 20 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a robot such as an industrial robot, an Internet of things device, a stereo system, a digital music player, a radio, a camera such as a digital camera, a portable memory chip, a home appliance such as a washer or a dryer, a peripheral device, a wrist watch, a clock, etc. Further, the electronic devices can include unfinished products.

Unless the context indicates otherwise, throughout the description and the claims, the words “comprise,” “comprising,” “include,” “including” and the like are to generally be construed in an inclusive sense, as opposed to an exclusive or exhaustive sense; that is to say, in the sense of “including, but not limited to.” Conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively.

While certain embodiments have been described, these embodiments have been presented by way of example only, and are not intended to limit the scope of the disclosure. Indeed, the novel resonators, filters, multiplexer, devices, modules, wireless communication devices, apparatus, methods, and systems described herein may be embodied in a variety of other forms. Furthermore, various omissions, substitutions, and changes in the form of the resonators, filters, multiplexer, devices, modules, wireless communication devices, apparatus, methods, and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and/or acts of the various embodiments described above can be combined to provide further embodiments. The accompanying claims and their equivalents are intended to cover such forms or modifications as would fall within the scope and spirit of the disclosure.

What is claimed is:

1. A bulk acoustic wave resonator having an acoustically active region and a peripheral region, the bulk acoustic wave resonator comprising:
electrodes including a first electrode and a second electrode;
a piezoelectric layer positioned between the first electrode and the second electrode, the piezoelectric layer having an effective piezoelectric coefficient with a lower magnitude in the peripheral region than in the acoustically active region; and
a recessed frame structure at least partially in the acoustically active region.

2. The bulk acoustic wave resonator of claim 1 further comprising a passivation layer including a first portion and a second portion thinner than the first portion, the recessed frame structure including the second portion of the passivation layer.

3. The bulk acoustic wave resonator of claim 2 further comprising an oxide raised frame structure in the peripheral region.

4. The bulk acoustic wave resonator of claim 1 wherein the recessed frame structure is offset from the peripheral region.

5. The bulk acoustic wave resonator of claim 1 wherein an entirety of the recessed frame structure is in the acoustically active region.

6. The bulk acoustic wave resonator of claim 1 further comprising a raised frame structure in the peripheral region.

7. The bulk acoustic wave resonator of claim 6 wherein the raised frame structure includes a metal layer in contact with the second electrode.

8. The bulk acoustic wave resonator of claim 6 wherein the raised frame structure includes a dielectric layer between the piezoelectric layer and the second electrode.

9. The bulk acoustic wave resonator of claim 1 wherein the first electrode has a first thickness in the acoustically active region and a second thickness in the peripheral region, and the second thickness is greater than the first thickness.

10. The bulk acoustic wave resonator of claim 9 wherein a magnitude of a positive mass loading provided by a thickness difference between the first and second thicknesses is greater than a magnitude of a negative mass loading provided by the recessed frame structure.

11. The bulk acoustic wave resonator of claim 1 further comprising a seed layer in the peripheral region between the first electrode and the piezoelectric layer.

12. The bulk acoustic wave resonator of claim 1 wherein the recessed frame structure includes a recessed portion of the second electrode.

13. A bulk acoustic wave resonator having an acoustically active region and a peripheral region, the bulk acoustic wave resonator comprising:
a first electrode including a thinner portion in the acoustically active region and a thicker portion in the peripheral region, the thicker portion being thicker than the thinner portion;
a second electrode;
a piezoelectric layer positioned between the first electrode and the second electrode, the piezoelectric layer having an effective piezoelectric coefficient with a lower magnitude in the peripheral region than in the acoustically active region; and
a recessed frame structure at least partially in the acoustically active region.

14. The bulk acoustic wave resonator of claim 13 wherein a magnitude of a positive mass loading provided by the thicker portion is greater than a magnitude of a negative mass loading provided by the recessed frame structure.

15. The bulk acoustic wave resonator of claim 13 wherein the recessed frame structure is completely in the acoustically active region.

16. The bulk acoustic wave resonator of claim 15 wherein the recessed frame structure is offset from the peripheral region.

17. The bulk acoustic wave resonator of claim 13 wherein the recessed frame structure includes a recessed portion of the second electrode.

18. The bulk acoustic wave resonator of claim 13 further comprising a seed layer positioned between the first electrode and the piezoelectric layer in the peripheral region.

19. The bulk acoustic wave resonator of claim 13 further comprising a raised frame structure in the peripheral region.

20. An acoustic wave filter for filtering a radio frequency signal, the acoustic wave filter comprising:
a bulk acoustic wave resonator having an acoustically active region and a peripheral region, the bulk acoustic wave resonator including electrodes including a first electrode and a second electrode; a piezoelectric layer positioned between the first electrode and the second electrode, the piezoelectric layer having an effective piezoelectric coefficient with a lower magnitude in the peripheral region than in the acoustically active region; and a recessed frame structure at least partially in the acoustically active region; and
a plurality of additional acoustic wave resonators, the bulk acoustic wave resonator and the plurality of additional acoustic wave resonators configured to filter the radio frequency signal.
